(19) United States
(12) Patent Application Publication
(10) Pub. No.: US 2025/0063704 A1
(43) Pub. Date: Feb. 20, 2025

(54) ELECTRONIC COMPUTING DEVICE FOR AN ASSISTANCE SYSTEM OF A MOTOR VEHICLE, ASSISTANCE SYSTEM AS WELL AS METHOD FOR PRODUCING AN ELECTRONIC COMPUTING DEVICE

(71) Applicant: CONNAUGHT ELECTRONICS Ltd., Tuam, County Galway (IE)

(72) Inventors: Shane Trout, Tuam, County Galway (IE); Beniamin Dragoi, Troy, MI (US)

(73) Assignee: CONNAUGHT ELECTRONICS Ltd., Tuam, County Galway (IE)

(21) Appl. No.: 18/576,749

(22) PCT Filed: Jul. 5, 2022
(86) PCT No.: PCT/EP2022/068526

§ 371 Date: Jan. 5, 2024

(30) Foreign Application Priority Data
Jul. 5, 2021 (DE) 10 2021 117 275.6

(51) Int. Cl. H05K 7/20

(52) U.S. Cl. CPC H05K 7/20872; H05K 7/20272

(57) ABSTRACT

An electronic computing device for an assistance system of a motor vehicle is disclosed. The device includes a first housing. A first processor device of the assistance system is arranged in a first internal space of the first housing and generates heat during operation. The device also includes a cooling device for cooling the first processor device. The cooling device is formed on a first outer wall of the first housing. A separate second housing with a second internal space is arranged stacked on the first housing viewed along a vertical direction of the electronic computing device. A second processor device of the assistance system is arranged in the second internal space. The second processor device generates heat during operation. A columnar structure of the cooling device is formed on a first outer side of the first outer wall.

The invention relates to an electronic computing device for an assistance system of a motor vehicle, with at least a first housing, wherein at least a first processor device of the assistance system is arranged in a first internal space of the first housing, wherein the first processor device generates heat at least in the operation, and with a cooling device for cooling the first processor device, which is formed on a first outer wall of the first housing. Further, the invention relates to an assistance system with at least one electronic computing device as well as to a method for producing an electronic computing device.

Motor vehicles are already known from the prior art, which comprise an electronic computing device, wherein the electronic computing device for example comprises processor devices for example on a circuit board. The processor devices generate heat in particular in the operation. Therein, the processor devices can be formed for executing computer programs with program codes, wherein heat is correspondingly generated in executing these computer commands. Therein, the processor devices can for example include integrated circuits and further electronic components. If the temperature within the electronic computing device should become too great, thus, this can result in a reduced computing power of the electronic computing device or even in the destruction of the electronic computing device on the one hand. Therefore, it is of crucial importance that the heat can be correspondingly dissipated and that cooling of the electronic computing device is performed, respectively. Hereto, air cooling systems or fluidic cooling systems are also already known from the prior art, which can dissipate the generated heat from the processor device via a corresponding cooling device, whereby increase of power as well as increase of lifetime of the electronic computing device can be realized.

Further, it is known from the prior art that different assistance functions can be provided in the motor vehicle. For example, assistance functions for an at least partially autonomous operation of the motor vehicle and assistance functions for the operation of capturing devices or infotainment systems, respectively, can be provided. In particular, today's motor vehicles have a plurality of different assistance functions. Therefore, a plurality of different processor devices are required within the motor vehicle to be able to provide the corresponding different assistance functions. Therefore, it is also of crucial importance to provide an electronic computing device with as many processor devices as possible, which can be cooled and is formed installation space saving at the same time. Therefore, it is already known in the prior art that stacking of processor devices can for example be performed, wherein a cooling device can then for example be formed between the respective processor devices viewed in a stacking direction, such that both processor devices can be cooled via a single cooling device in the stacked state.

U.S. Pat. No. 6,655,326 B2 discloses that a motor with an electronic motor control unit is provided with a temperature management system for the electronic motor control unit to prevent a failure of the motor control unit by overheating. The temperature management system includes means for monitoring or evaluating the temperature of the motor control unit to determine when the temperature of the motor control unit approaches a predetermined limit value, and means for limiting the further heating of the motor control unit to prevent the mentioned limit value from being exceeded.

It is the object of the present invention to provide an electronic computing device, an assistance system as well as a method for producing an electronic computing device, by means of which an efficient cooling as well as a simple exchange of a processor device within the electronic computing device can be realized.

This object is solved by an electronic computing device, an assistance system as well as by a method for producing an electronic computing device according to the independent claims. Advantageous forms of configuration are specified in the dependent claims.

An aspect of the invention relates to an electronic computing device for an assistance system of a motor vehicle, with at least a first housing, wherein at least a first processor device of the assistance system is arranged in a first internal space of the first housing, wherein the first processor device generates heat at least in the operation, and with a cooling device for cooling the first processor device, which is formed on a first outer wall of the first housing.

It is provided that a separate second housing with a second internal space is arranged stacked on the first housing viewed along a vertical direction of the electronic computing device, wherein at least a second processor device of the assistance system is arranged in the second internal space, wherein the second processor device generates heat at least in the operation, and wherein the second housing is arranged on the cooling device at least in certain areas with a second outer wall opposing the first outer wall, such that the cooling device is bounded by the first outer wall and the second outer wall at least in certain areas and is additionally formed for cooling the second processor device.

Thus, both the first processor device and the second processor device can be cooled by means of a single cooling device. Further, the second separate housing can be simply exchanged from the first separate housing. For example, if renewal or change should be performed within the second processor device, thus, the entire electronic computing device in the motor vehicle does not have to be exchanged, but only the second processor device can be removed from the electronic computing device and from the first housing, respectively, and for example be replaced with a new second processor device. For example, if a user or driver of the motor vehicle should buy or book an extended function within the motor vehicle, thus, an exchange of the second processor device for the newly bought functions can further be performed, and an entire exchange of the electronic computing device can be prevented. Thus, a new function can be implemented in the motor vehicle in simple manner and reduced in assembly.

In particular, the first processor device can be formed as a so-called master processor device and the second processor device can be formed as a so-called satellite processor device. The processor device can in particular also be referred to as electronic circuit unit (ECU). Therein, the processor devices can for example include integrated circuits and further electronic components.

Further, it is in particular provided that the first processor device and the second processor device generate heat in the operation. In particular by executing corresponding computer commands, heat arises, which is to be transported away via the cooling device. Thereby, the computing power of the first processor device and the second processor device can be increased as well as the corresponding lifetime of the first processor device and of the second processor device can be increased. In particular, the first processor device and the second processor device are so-called high-performance processor devices. According to the proposed concept, thus, it is in particular provided that the first processor device and the second processor device are substantially stacked on top of each other. The corresponding outer walls of the housings are respectively located between the stacked processor devices and the cooling device is in turn located therebetween, which is in particular formed as a so-called cooling duct. In particular, the term stacked on top of each other relates to the positioning of the processor devices to each other. In particular, the corresponding processor devices do not contact each other.

In particular, at least the outer housing wall and correspondingly the cooling device is formed between the respective inner surfaces of the processor devices.

Therein, the first processor device and the second processor device can for example partially or also completely overlap. Thus, the second processor device can for example be smaller than the first processor device and be completely or substantially completely overlapped by the first processor device.

That the cooling device is arranged between the first processor device and the second processor device, can in particular be understood such that the first processor device, the cooling device and the second processor device are arranged stacked on top of each other in the mentioned order. In particular, at least a part of the cooling device is formed overlapping by the first processor device and the second processor device such that the respective part of the cooling device is formed between the first processor device and the second processor device.

In particular by the present arrangement of the respective processor devices and the cooling device to each other according to the proposed concept, a particularly compact arrangement for the electronic computing device with the two processor devices as well as the cooling device is achieved. Therein, the cooling device allows particularly efficiently cooling the respective processor devices. Further, the proposed concept allows simply removing or exchanging the second processor device without having to perform an entire exchange of the electronic computing device within the motor vehicle.

Thereby, a particularly great power dissipation can in particular be handled, which allows the use of components with high computing power. By providing the electronic computing device with the two processor devices, the available computing power in the motor vehicle can be further increased and/or the corresponding processor devices can provide an increased redundancy level and therefore a greater functional safety.

According to an advantageous form of configuration, the second housing is non-destructively detachably arranged on the first housing. By non-destructively detachable, it is in particular to be understood that the second housing can be removed from the first housing without therein impairing the first housing. Thus, an exchange of the second processor device can for example be performed without therein performing an impairment of the first housing. For example, the second housing can be connected to the first housing via corresponding screw elements. The screw elements can then be correspondingly removed as needed without therein performing an impairment of the first housing. Thus, a simple exchange or a simple replacement of the second processor device can be performed on the first housing.

It is further advantageous if a first assistance function of the assistance system is provided in the first processor device and a second assistance function of the assistance system formed different from the first assistance function is provided in the second processor device. For example, a driver assistance function can be provided within the first processor device, which is installed in the motor vehicle by default. An assistance function can be formed in the second processor device, which can be additionally bookable by the user. If the user should now correspondingly desire to change or exchange the second assistance function, thus, this can be performed by removing the second processor device from the electronic computing device in simple manner without having to exchange the entire electronic computing device in the motor vehicle.

In a further advantageous form of configuration, the cooling device is formed as a fluidic cooling device. Thus, a cooling fluid can in particular circulate within the cooling device and realize the heat transport within the cooling device. The cooling fluid is in particular a fluid, which can absorb a high heat yield and thus can increase the computing power of the electronic computing device by the cooling. The cooling fluid can for example be a cooling fluid of a further cooling circuit of the motor vehicle. The motor vehicle can for example comprise a fluid reservoir, from which the cooling fluid can be withdrawn.

Further, it has proven advantageous if a first top side of the first processor device is contacted with a first inner side of the first outer wall via a heat conducting element and/or a second top side of the second processor device is contacted with a second inner side of the second outer wall via a heat conducting element. For example, the respective heat conducting element can be a heat conducting paste or a heat conducting pad, which can release the heat of the first processor device to the outer wall and the heat of the second processor device to the respective outer wall, respectively, in improved manner. Thus, an improved heat transport from the respective processor devices to the respective outer wall can be realized such that the heat transport out of the electronic computing device can then in turn be realized via the corresponding cooling device.

In a further advantageous form of configuration, the first processor device is electrically connected to the second processor device via a contact device. Thus, the first processor device and the second processor device can in particular exchange electrical signals to for example be able to perform a common assistance function. The contact device is in particular a high-speed contact device such that corresponding signals can be very fast exchanged between the processor devices. Thereby, an improved function of the electronic computing device can be realized. Further, the simple exchange of the second processor device can be performed since only the contact device has to be disconnected.

Further, it has proven advantageous if the contact device is formed as a plug connection. Thus, a simple removal of the second processor device from the first processor device can in particular be performed by a plugging process. Thus, a simple exchange of the second processor device within the electronic computing device can be realized.

In a further advantageous form of configuration, the contact device is passed through the first outer wall and the second outer wall and the contact device is formed outside of a cooling area of the cooling device. In particular if the cooling device is fluidically formed, thus, the contact of the cooling fluid with the contact device can be prevented. Thereby, the electrical signals can for example be prevented from contacting the cooling fluid, whereby short circuits or incorrectly transmitted signals could for example occur. Thereby, a simple assembly and an improved operation of the electronic computing device can be realized.

Further, it has proven advantageous if the first housing and/or the second housing are formed of aluminum at least in certain areas. In particular, the first housing and the second housing are formed of aluminum at least in the area of the cooling device, which can also be referred to as cooling area. Aluminum in particular has the advantage that it can very effectively transport the heat away and for example can be simply formed. Thereby, the heat can be released from the first processor device and the second processor device to the cooling device in improved manner.

In a further advantageous form of configuration, a columnar first structure of the cooling device, in particular on the cooling area of the cooling device, is formed on a first outer side of the first outer wall and/or a columnar second structure of the cooling device, in particular on the cooling area of the cooling device, is formed on a second outer side of the second outer wall opposing the first outer side. Thereby, the surface of the respective housings can in particular be increased, whereby improved cooling performance can be realized since more heat can be in particular transported via the housing into the cooling device. Then, the cooling device can in turn absorb more heat by flowing past the columnar structure and transport it away in improved manner. The columnar structure can also be referred to as pins. Thereby, an improved operation of the electronic computing device can be realized.

It is also advantageous if the first structure and the second structure are formed engaging with each other. Thus, the first columnar structure and the second columnar structure in particular engage with each other such that the second columnar structure extends in the clearances between the first columnar structure in the assembled state and vice versa. Thereby, an improved cooling of the first processor device and the second processor device can be realized reduced in installation space.

Further, it has proven advantageous if a cooling inlet and a cooling outlet are formed on a rear side of the first housing, wherein the cooling inlet is connected to the cooling outlet via the cooling device. The cooling inlet and the cooling outlet are in particular corresponding openings, which allow a cooling fluid to flow into the cooling device. Therein, the cooling inlet and the cooling outlet can be filled with cooling water, which is for example provided by the motor vehicle. In particular, corresponding plug elements are formed at the cooling outlet and at the cooling inlet, which allow a connection to for example a cooling water tank or cooling water reservoir. Thus, a simple assembly of the electronic computing device and simple cooling of the electronic computing device at the same time can be realized within the motor vehicle.

It is also advantageous if the cooling device comprises a cooling area and the cooling inlet is connected to the cooling area via a coolant directing element and/or the cooling outlet is connected to the cooling area via a coolant directing element. For example, if the cooling inlet and the cooling outlet should be formed on the rear side, thus, an improved “flow” of the cooling fluid with reduced friction can in particular be realized within the cooling device via the cooling directing element at the inlet and the cooling directing element at the outlet, respectively, whereby a higher amount of heat can be absorbed by the cooling fluid. Thus, the cooling fluid is in particular conducted from the cooling inlet via the cooling directing element to the cooling area, for example with the columnar structure, and transported from the cooling area with the columnar structure, in particular via the cooling directing element, again to the cooling outlet. Therein, the cooling directing element can be rib-like formed. Further, the cooling directing element can also comprise a plurality of ribs such that an increased cooling fluid volume can advantageously also be carried within the cooling device.

A further aspect of the invention relates to an assistance system for a motor vehicle with at least one electronic computing device according to the preceding aspect. Therein, the assistance system in particular comprises at least a first assistance function as well as a second assistance function different from the first assistance function. Therein, the first assistance function can for example be formed on the first processor device of the electronic computing device and the second assistance function can be formed on the second processor device of the electronic computing device.

A still further aspect of the invention relates to a motor vehicle with an electronic computing device according to the preceding aspect and/or with an assistance system according to the preceding aspect. Therein, the motor vehicle can for example be at least partially autonomously or fully autonomously formed. In particular, the motor vehicle comprises at least corresponding assistance functions.

A still further aspect of the invention relates to a method for producing an electronic computing device for a motor vehicle according to the preceding aspect, wherein a first processor device is provided in a first housing.

The method is characterized in that a second processor device is provided in a separate second housing, wherein the first processor device and the second processor device are arranged stacked viewed in a vertical direction, and that a cooling device for cooling the first processor device and the second processor device is formed between respective outer walls of the housings.

Advantageous forms of configuration of the electronic computing device are to be regarded as advantageous forms of configuration of the assistance system, of the motor vehicle as well as of the method for producing the electronic computing device.

Further features of the invention are apparent from the claims, the figures, and the description of figures. The features and feature combinations mentioned above in the description as well as the features and feature combinations mentioned below in the description of figures and/or shown in the figures alone are usable not only in the respectively specified combination, but also in other combinations without departing from the scope of the invention. Thus, implementations are also to be considered as encompassed and disclosed by the invention, which are not explicitly shown in the figures and explained, but arise from and can be generated by separated feature combinations from the explained implementations. Implementations and feature combinations are also to be considered as disclosed, which thus do not comprise all of the features of an originally formulated independent claim. Moreover, implementations and feature combinations are to be considered as disclosed, in particular by the implementations set out above, which extend beyond or deviate from the feature combinations set out in the relations of the claims.

Now, the invention is explained in more detail based on preferred embodiments as well as with reference to the attached drawings.

There show:

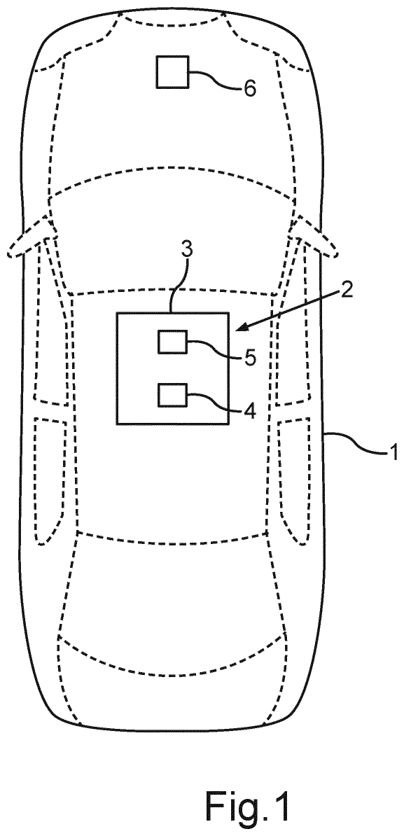

FIG. 1 a schematic top view to an embodiment of a motor vehicle with an embodiment of an assistance system;

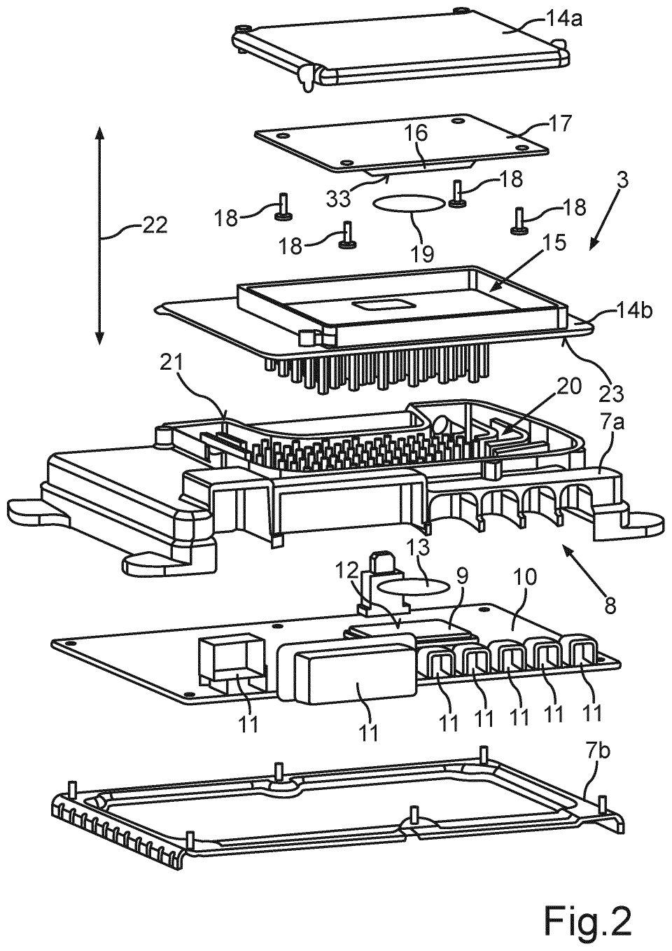

FIG. 2 a schematic exploded representation of an embodiment of an electronic computing device;

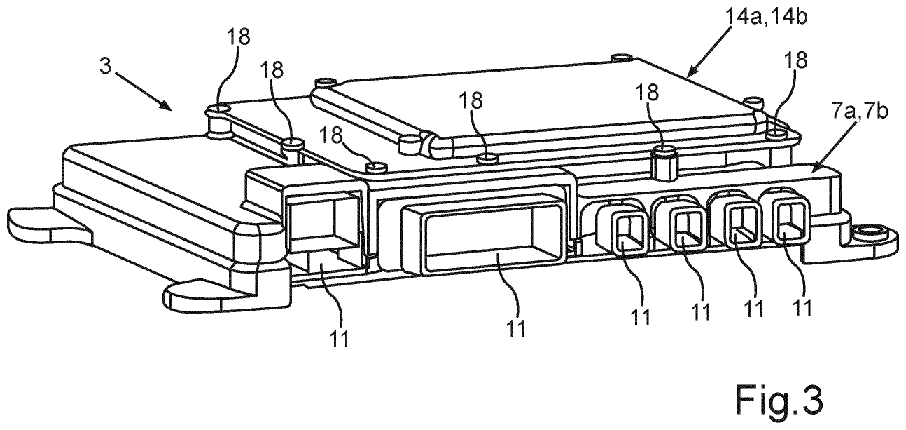

FIG. 3 a schematic perspective view of an embodiment of an electronic computing device;

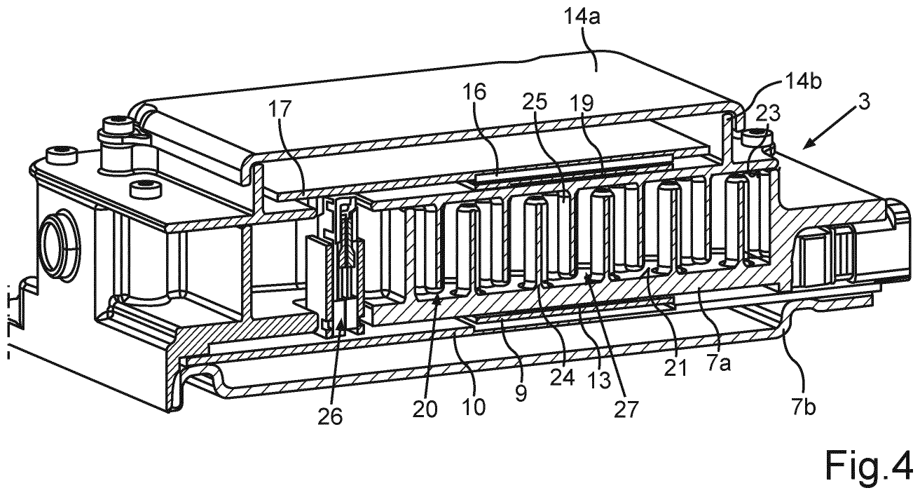

FIG. 4 a schematic sectional view according to an embodiment of an electronic computing device;

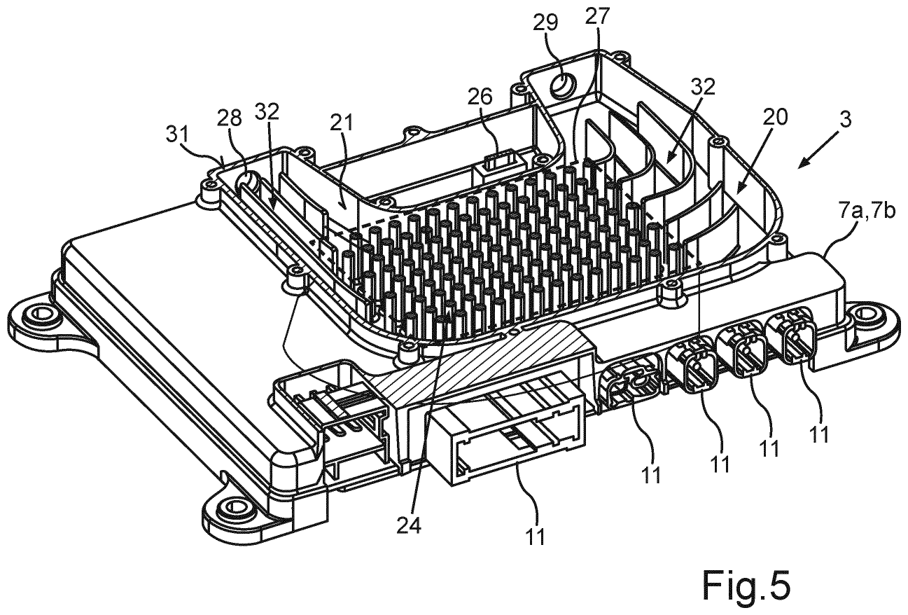

FIG. 5 a schematic top view to a part of an embodiment of an electronic computing device;

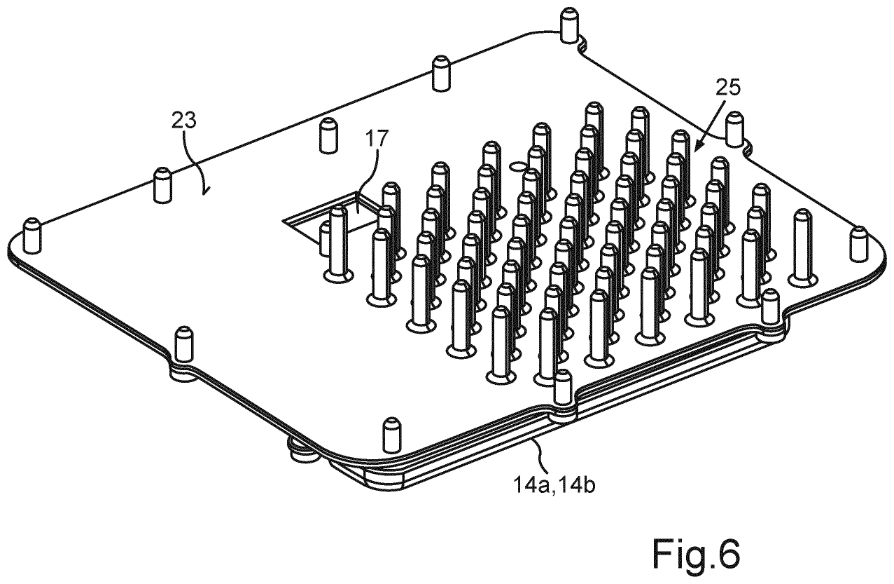

FIG. 6 a further schematic top view to a further part of an embodiment of the electronic computing device;

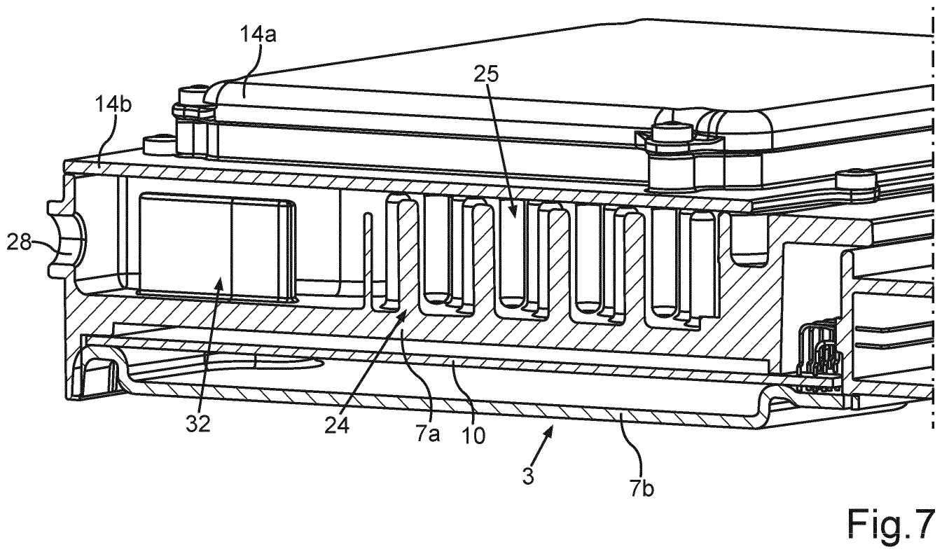

FIG. 7 a further schematic sectional view of an embodiment of an electronic computing device; and

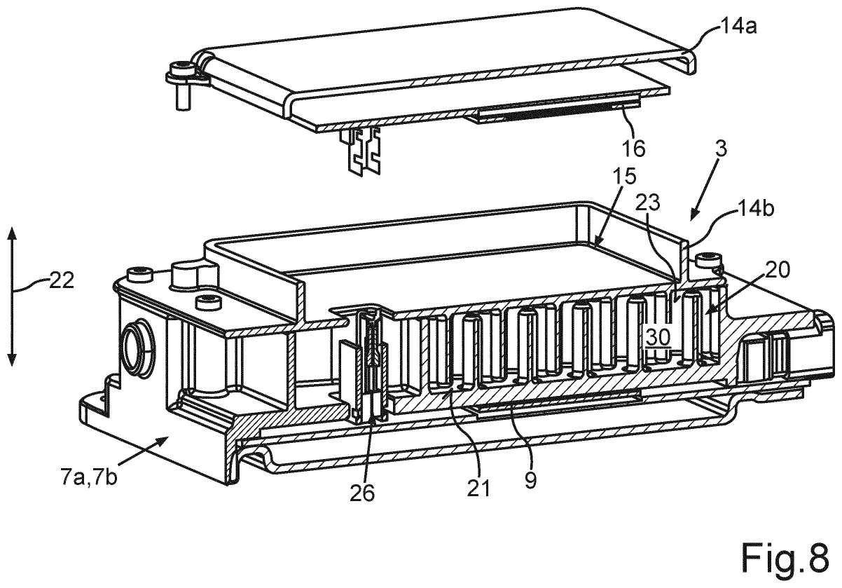

FIG. 8 a perspective sectional view according to a method for producing an embodiment of an electronic computing device.

In the figures, identical or functionally identical elements are provided with the same reference characters.

FIG. 1 shows a schematic top view to an embodiment of a motor vehicle 1 with an embodiment of an assistance system 2. In particular, the assistance system 2 comprises at least one electronic computing device 3, which is presently purely schematically illustrated. The assistance system 2 in particular comprises at least a first assistance function 4 as well as a second assistance function 5. Therein, the assistance functions 4, 5 can be formed both for a drive operation of the motor vehicle 1, for example for an at least partially autonomous drive operation or a fully autonomous drive operation of the motor vehicle 1. Alternatively or additionally, the assistance functions 4, 5 can for example also be formed for the operation of capturing devices 6 as well as for the operation of for example an infotainment system.

FIG. 2 shows a schematic exploded representation according to an embodiment of the electronic computing device 3. Therein, the electronic computing device 3 comprises a first housing 7a, 7b, which is presently shown by an upper housing part 7a and a lower housing part 7b. The first housing 7a, 7b in particular forms an internal space 8, wherein a first processor device 9 is formed on a first circuit board 10 in the internal space 8. Further, FIG. 2 shows different plug contacts 11, which can be led out of the first housing 7a, 7b. In particular, an electrical current supply and corresponding contact plugs for signal processing and for signal exchange, respectively, can for example be provided by the plug contacts 11. In particular, a first heat conducting element 13 can be formed on a first top side 12 of the first processor device 9.

Further, the electronic computing device 3 comprises a second housing 14a, 14b, which is presently shown by two housing parts 14a and 14b. A second internal space 15 is formed in the second housing 14a, 14b, in which a second processor device 16, presently in particular on a second circuit board 17, can in particular be arranged. Further, it is in particular shown that the first housing part 14a presently can be connected to the second housing part 14b via corresponding screw elements 18. Further, a second heat conducting element 19 can also be formed on the second processor device 16.

Thus, FIG. 2 in particular shows the electronic computing device 3 with at least a first housing 7a, 7b in an exploded representation, wherein at least the first processor device 9 is formed in the first internal space 8, wherein the first processor device 9 generates heat at least in the operation. Further, it is in particular shown that the electronic computing device 3 can comprise a cooling device 20 for cooling the first processor device 9, wherein the cooling device 20 is formed on a first outer wall 21 of the first housing 7a, 7b.

In particular, it is shown that the separate second housing 14a, 14b with the second internal space 15 is arranged stacked on the first housing 7a, 7b viewed along a vertical direction 22 of the electronic computing device 3, wherein at least the second processor device 16 of the assistance system 2 is arranged in the second internal space 15, wherein the second processor device 16 generates heat at least in the operation and wherein the second housing 14a, 14b is arranged on the cooling device 20 at least in certain areas with a second outer wall 23 opposing the first outer wall 21, such that the cooling device 20 is bounded by the first outer wall 21 and the second outer wall 23 at least in certain areas and is additionally formed for cooling the second processor device 16.

In particular, FIG. 2 further shows that the second housing 14a, 14b is non-destructively detachably arranged on the first housing 7a, 7b, for example via corresponding screw elements 18.

FIG. 3 shows a schematic perspective view of an embodiment of the electronic computing device 3 in the assembled state. In particular, it is shown that the second housing 14a, 14b is arranged, in particular screwed, on the first housing 7a, 7b.

FIG. 4 shows a schematic perspective view according to an embodiment of the electronic computing device 3. Presently, it is in particular shown that the first processor device 9 and the second processor device 16 are substantially arranged stacked on top of each other. The first processor device 9 is coupled to the heat conducting element 13 on the first top side 12 and in particular connected to the first outer wall 21. The second processor device 16 is coupled to the second outer wall 23 via a second top side 33 and the second heat conducting element 19. Presently, the cooling device 20 comprises a first columnar structure 24 as well as a second columnar structure 25. Therein, the first columnar structure 24 is formed on the first outer wall 21 and the second columnar structure 25 is formed on the second housing wall 23.

Thus, in the operation of the first processor device 9, the first processor device 9 releases heat to the first heat conducting element 13, wherein the first heat conducting element 13 is in turn coupled to the first outer wall 21. Thus, heat is released from the first heat conducting element 13 to the first outer side 21, which is presently in turn in particular connected to the first columnar structure 24. Thus, the heat can be transferred to the columnar structure 24. The same results with the second columnar structure 25. The generated heat of the second processor device 16 is released via the second heat conducting element 19 to the second outer wall 23, which is in turn in contact with the second columnar structure 25. The first columnar structure 24 and the second columnar structure 25 can in turn be washed around by a cooling fluid 30 (see FIG. 8) and the heat can be transferred to the cooling fluid 30, whereby the heat can be transported away from the electronic computing device.

As presently shown, the first columnar structure 24 and the second columnar structure 25 are formed such that they engage with each other. In other words, the respective column of the second columnar structure 25 is formed between respective columns of the first columnar structure 24.

Further, FIG. 4 in particular shows a contact device 26. In particular, the contact device 26 is formed as a high-performance or high-speed contact device 26. In particular, the contact device 26 electronically and/or electrically connects the first processor device 9 to the second processor device 16 such that electrical signals can for example be transmitted from the first processor device 9 to the processor device 16 or vice versa. Further, an electrical energy supply of the second processor device 16 can also be realized via the first processor device 9 such that additional plug contacts do not have to be formed on the second housing 14a, 14b. Thus, common computing power can for example be realized. Therein, the contact device 26 is in particular formed as a plug device, and thus a simple removal of the second processor device 16 can be realized via the contact device 26. Further, it is in particular shown that the contact device 26 extends through the first outer wall 21 and the second outer wall 23, wherein the contact device 26 is located outside of a cooling area 27 of the cooling device 20.

FIG. 5 shows a further schematic top view to a part of the electronic computing device 3, in particular to the first housing 7a, 7b. In particular, a top view to the first outer wall 21 is shown. FIG. 5 in particular shows the cooling device 20. The cooling device 20 comprises the cooling area 27, wherein the cooling area 27 in turn shows the first columnar structure 24. Further, a cooling inlet 28 and a cooling outlet 29 are in particular shown. Presently, they are purely exemplarily formed and can for example also be formed interchanged. In particular, the cooling fluid 30 can then in turn be passed via the cooling inlet 28 into the cooling area 27. In particular, the cooling inlet 28 and the cooling outlet 29 are formed on a rear side 31 of the first housing 7a, 7b. Further, FIG. 5 shows that the cooling device 20 comprises the cooling area 27 and the cooling inlet 28 is connected to the cooling area 27 via a coolant directing element 32 and/or the cooling outlet 29 is connected to the cooling area 27 via a cooling directing element 32. Presently, the respective cooling directing elements 32 are in particular shown as a plurality of rib-like structures such that a cooling fluid 30 can be directed from the cooling inlet 28 and can flow into the cooling area 27 in improved manner, in particular reduced in friction. Then, the already heated liquid can in turn also be directed towards the cooling outlet 29 via the further rib-like structure at the cooling outlet 29. Thereby, an improved fluid flow can be realized within the cooling device 20 reduced in friction.

FIG. 6 shows a schematic perspective view to an embodiment of the second housing 14a, 14b. In particular, the bottom side, in particular the second outer wall 23, is shown. Further, the second columnar structure 25 is illustrated.

FIG. 7 shows a further schematic sectional view according to an embodiment of the electronic computing device 3. In particular, a section through the plane is shown, in which the cooling inlet 28 is illustrated in sectioned manner. Further, FIG. 7 also shows the cooling directing element 32 towards the first columnar structure 24 and the second columnar structure 25.

FIG. 8 shows a schematic sectional view according to an embodiment of the electronic computing device 3, wherein in particular a production method is presently shown. In particular, it is shown that the second part of the second housing 14a, 14b is already arranged on the cooling device 20. Thus, the cooling circuit of the cooling device 20 is already closed. Subsequently thereto, the second processor device 16 is in turn passed into the second internal space 15 and closed by the lid element of the second housing 14a, 14b. Then, an electrical contact between the first processor device 9 and the second processor device 16 can in turn be realized by the contact device 26.

Thus, a method for producing the electronic computing device 3 is in particular shown in FIG. 8, wherein at least the first processor device 9 is provided in the first housing 7a, 7b and the second processor device 16 is provided in a separate second housing 14a, 14b, wherein the first processor device 9 and the second processor device 16 are arranged stacked viewed in the vertical direction 22 and that the cooling device 20 for cooling the first processor device 9 and the second processor device 16 is formed between the respective outer walls 21, 23 of the housings 7a, 7b, 14a, 14b.

In particular, it can be provided that at least the first housing 7a, 7b and the second housing 14a, 14b are partially produced or provided of aluminum.

1. An electronic computing device for an assistance system of a motor vehicle, the device comprising:
a first housing,
wherein at least a first processor device of the assistance system is arranged in a first internal space of the first housing,
wherein the first processor device generates heat at least in the operation; and
a cooling device for cooling the first processor device,
wherein the cooling device is formed on a first outer wall of the first housing,
wherein a separate second housing with a second internal space is arranged stacked on the first housing viewed along a vertical direction of the electronic computing device,
wherein at least a second processor device of the assistance system is arranged in the second internal space,
wherein the second processor device generates heat at least in the operation,
wherein the second housing is arranged on the cooling device at least in certain areas with a second outer wall opposing the first outer wall such that the cooling device is bounded by the first outer wall and the second outer wall at least in certain areas and is additionally formed for cooling the second processor device,
wherein a columnar structure of the cooling device in a cooling area of the cooling device is formed on a first outer side of the first outer wall, and
wherein a columnar second structure of the cooling device is formed on a second outer side of the second outer wall opposing the first outer side.

2. The electronic computing device according to claim 1,
wherein the second housing is non-destructively detachably arranged on the first housing.

3. The electronic computing device according to claim 1,
wherein a first assistance function of the assistance system is provided in the first processor device, and
wherein a second assistance function of the assistance system is provided in the second processor device,
wherein the second assistance function is formed different from the first assistance function.

4. The electronic computing device according to claim 1,
wherein the cooling device is formed as a fluidic cooling device with a cooling fluid.

5. The electronic computing device according to claim 1,
wherein a first top side of the first processor device is contacted with a first inner side of the first outer wall via a first heat conducting element, and
wherein a second top side of the second processor device is contacted with a second inner side of the second outer wall via second heat conducting element.

6. The electronic computing device according to claim 1,
wherein the first processor device is electrically connected to the second processor device via a contact device.

7. The electronic computing device according to claim 6,
wherein the contact device is formed as a plug connection.

8. The electronic computing device according to claim 6,
wherein the contact device is passed through the first outer wall and the second outer wall, and
wherein the contact device is formed outside of a cooling area of the cooling device.

9. The electronic computing device according to claim 1,
wherein the first housing and the second housing are formed at least partly of aluminum.

10. (canceled)

11. The electronic computing device according to claim 1,
wherein the first structure and the second structure are formed engaging with each other.

12. The electronic computing device according to claim 1,
wherein a cooling inlet and a cooling outlet are formed on a rear side of the first housing,
wherein the cooling inlet is connected to the cooling outlet via the cooling device.

13. The electronic computing device according to claim 12,
wherein the cooling device comprises a cooling area,
wherein the cooling inlet is connected to the cooling area via a coolant directing element, and
wherein the cooling outlet is connected to the cooling area via a coolant directing element.

14. An assistance system for a motor vehicle with at least one electronic computing device according to claim 1.

15. A method for producing an electronic computing device for a motor vehicle according to claim 1,
wherein a first processor device is provided in a first housing, wherein a second processor device is provided in a separate second housing,
wherein the first processor device and the second processor device are arranged stacked viewed in a vertical direction, and
wherein a cooling device for cooling the first processor device and the second processor device is formed between the respective outer walls of the housings.
